(19) United States
(12) Patent Application Publication
(10) Pub. No.: US 2024/0010915 A1
(43) Pub. Date: Jan. 11, 2024

(54) Etching Solution For Titanium Nitride And Molybdenum Conductive Metal Lines

(71) Applicant: Versum Materials US, LLC, Tempe, AZ (US)

(72) Inventors: CHAO-HSIANG CHEN, Hsinchu City (TW); JHIH KUEI GE, New Taipei City (TW); YI-CHIA LEE, Chupei City (TW); WEN DAR LIU, Chupei City (TW)

(73) Assignee: Versum Materials US, LLC, Tempe, AZ (US)

(21) Appl. No.: 17/905,340

(22) PCT Filed: Mar. 2, 2021
(86) PCT No.: PCT/US2021/020377

§ 371 Date: Aug. 31, 2022

Related U.S. Application Data
(60) Provisional application No. 62/985,136, filed on Mar. 4, 2020.

(51) Int. Cl. C09K 13/08; C23F 1/26; H01L 21/311; H01L 21/3213

(52) U.S. Cl. CPC C09K 13/08; C23F 1/26; H01L 21/31111; H01L 21/32134

(57) ABSTRACT

Etching composition suitable for etching titanium nitride and molybdenum from a microelectronic device, which includes, consists essentially of, or consists of, in effective amounts: water; HNO₃; optionally, at least one chloride ion source selected from the group of NH₄Cl and HCl; a base selected from the group of an alkanolamine, NH₄OH, a quaternary ammonium hydroxide, and mixtures thereof; optionally, at least one fluoride ion source; optionally, at least one heteroaromatic compound; and optionally, at least one water-miscible solvent selected from the group of diethylene glycol butyl ether, sulfolane, and propylene carbonate.

### BACKGROUND

The disclosed and claimed subject matter relates to an etching composition, and more particularly, to an etching composition capable of etching a titanium nitride and molybdenum metal and to a method for fabricating a semiconductor, which includes an etching process employing the etching composition.

Semiconductor memory devices include volatile memory devices, such as dynamic random access memory (“DRAM”) or static random access memory (“SRAM”) devices, non-volatile memory devices, such as resistive random access memory (“ReRAM”), electrically erasable programmable read only memory (“EEPROM”), flash memory (which can also be considered a subset of EEPROM), ferroelectric random access memory (“FRAM”), and magnetoresistive random access memory (“MRAM”), and other semiconductor elements capable of storing information. Each type of memory device may have different configurations. For example, flash memory devices may be configured in a NAND or a NOR configuration.

Fabrication of semiconductor memory devices involves deposition and etching of multiple layers of materials in order to form a desired pattern of conductive paths in a layer of dielectric. Anisotropic etching (i.e., predominant etching in a selected direction) is a valuable tool for forming recessed features on semiconductor substrates. In a typical example of anisotropic etching, the material is etched out in a vertical direction, without horizontal etching. For example, the material can be removed from the bottom of a recessed feature, while preserving the width of the recessed feature.

A conventional vertical NAND string uses an aluminum oxide (Al oxide) etch-stop layer for stopping a high-aspect-ratio pillar (trench) etch (e.g., because the Al oxide etch-stop layer does not have sufficient etch selectivity, a relatively thicker layer of the Al oxide is needed in order to be able to control stopping of the etch). The relatively thicker Al oxide layer causes an undesirably longer channel distance between the select gate (SG) and the first wordline (WL) of the NAND string, thereby underutilizing the full length of the NAND string channel.

Tungsten (W) is widely employed as the material of conductive metal lines in 3D NAND devices. During fabrication of the 3D NAND memory device, tungsten (W) recess for word-line (WL) isolation is one of the key process steps. Typically, high-k/metal gate are used for the connection of tungsten control gate. In the recessing process TiN and W should be simultaneously etched with equal thickness. However, tungsten's high tensile stress can generate warpage of a device structure. Molybdenum is a softer metal than tungsten, and may be deposited employing a thinner metallic barrier material layer than a metallic barrier metal layer required for tungsten deposition. Furthermore, molybdenum has lower resistivity at thin dimensions to maintain overall device performance than tungsten. Word line W recess in 3D NAND memory fabrication process has shifted Mo metal to replace W. Mo has high activity than W in etch rate.

Molybdenum and molybdenum-containing materials have emerged as materials that find many uses in IC fabrication, both as conductive layers, and more recently as hardmasks in dynamic random-access memory (DRAM) and 3D NAND fabrication. While there is a variety of methods that can be used for molybdenum deposition, including chemical vapor deposition (CVD), atomic layer deposition (ALD), and physical vapor deposition (PVD), the methods for molybdenum etching are still limited.

For example, during fabrication of the 3D NAND memory device, molybdenum (Mo) recess for word-line (WL) isolation is one of the key process steps. Typically, high-k/metal gate are used for the connection of molybdenum control gate. In the recessing process TiN and Mo should be simultaneously etched with equal thickness. AlOx is the protecting layer that should not be damaged. As the number of layers increases, it is difficult to completely etch the bottom layer of Mo and TiN by dry etch-methods because the dry-etching by product from the top layer would remain in the trenches and restrict etching the bottom layer. Therefore, wet-etch method has been proposed as an alternative for a Mo recess.

Conventional wet-etch methods have technical challenges. Typical wet-etch chemicals would easily etch the AlOx and cause a recess in the side wall of the channel at the AlOx layer that forms an undesirable floating gate and results in an on-current degradation for the NAND string. Additionally, conventional wet etchants show low TiN or Mo etch rates that result in the extremely long process time (over 1 hr). The long process time means the wet etchant needs to be applied in a batch type tool and makes impractical the use of a single wafer tool (SWT) for that step.

Accordingly, there is a need in the art for compositions that will selectively removal of a TiN hard mask and a Mo metal conductor layer relative to other layers that may be present such as, for example, low-k dielectric layers.

### SUMMARY

In one aspect, the disclosed and claimed subject matter provides an etching composition suitable for etching titanium nitride and molybdenum from a microelectronic device, which includes, consists essentially of, or consists of, in effective amounts: water; HNO₃; optionally, at least one chloride ion source selected from the group consisting of NH₄Cl and HCl; a base selected from the group of an alkanolamine, NH₄OH, a quaternary ammonium hydroxide, and mixtures thereof; optionally, at least one fluoride ion source; optionally, at least one heteroaromatic compound; and optionally, at least one water-miscible solvent selected from the group of diethylene glycol butyl ether, sulfolane, and propylene carbonate.

In another aspect, the disclosed and claimed subject matter provides a method of selectively enhancing the etch rate of titanium nitride and molybdenum on a composite semiconductor device including titanium nitride and molybdenum, the method including the steps of: contacting the composite semiconductor device including titanium nitride and molybdenum with a composition which includes, consists essentially of, or consists of: water; HNO₃; optionally, at least one chloride ion source selected from the group consisting of NH₄Cl and HCl; a base selected from the group of an alkanolamine, NH₄OH, a quaternary ammonium hydroxide, and mixtures thereof, optionally, at least one fluoride ion source; optionally, at least one heteroaromatic compound; and optionally, at least one water-miscible solvent selected from the group of diethylene glycol butyl ether, sulfolane, and propylene carbonate; and rinsing the composite semiconductor device after the titanium nitride and molybdenum is at least partially removed.

The embodiments of the disclosed and claimed subject matter can be used alone or in combinations with each other.

### DETAILED DESCRIPTION

All references, including publications, patent applications, and patents, cited herein are hereby incorporated by reference to the same extent as if each reference were individually and specifically indicated to be incorporated by reference and were set forth in its entirety herein.

The ensuing detailed description provides preferred exemplary embodiments only, and is not intended to limit the scope, applicability, or configuration of the disclosed and claimed subject matter. Rather, the ensuing detailed description of the preferred exemplary embodiments will provide those skilled in the art with an enabling description for implementing the preferred exemplary embodiments of the disclosed and claimed subject matter. Various changes may be made in the function and arrangement of elements without departing from the spirit and scope of the disclosed and claimed subject matter, as set forth in the appended claims.

The use of the terms “a” and “an” and “the” and similar referents in the context of describing the disclosed and claimed subject matter (especially in the context of the following claims) are to be construed to cover both the singular and the plural, unless otherwise indicated herein or clearly contradicted by context.

As used herein and in the claims, the terms “comprising,” “comprises,” “including,” and “includes” are inclusive or open-ended and do not exclude additional unrecited elements, composition components, or method steps. Accordingly, these terms encompass the more restrictive terms “consisting essentially of” and “consisting of.” Unless specified otherwise, all values provided herein include up to and including the endpoints given, and the values of the constituents or components of the compositions are expressed in weight percent of each ingredient in the composition.

In compositions “consisting essentially of” recited components, such components may add up to 100 weight % of the composition or may add up to less than 100 weight %. Where the components add up to less than 100 weight %, such composition may include some small amounts of a non-essential contaminants or impurities. For example, in one such embodiment, the etching composition can contain 2% by weight or less of impurities. In another embodiment, the etching composition can contain 1% by weight or less than of impurities. In a further embodiment, the etching composition can contain 0.05% by weight or less than of impurities. In other such embodiments, the ingredients can form at least 90 wt %, more preferably at least 95 wt %, more preferably at least 99 wt %, more preferably at least 99.5 wt %, most preferably at least 99.9 wt %, and can include other ingredients that do not material affect the performance of the etching compositions. Otherwise, if no significant non-essential impurity component is present, it is understood that the combination of all essential constituent components will essentially add up to 100 weight %.

All methods described herein can be performed in any suitable order unless otherwise indicated herein or otherwise clearly contradicted by context. The use of any and all examples, or exemplary language (e.g., “such as”) provided herein, is intended merely to better illuminate the disclosed and claimed subject matter and does not pose a limitation on the scope of the disclosed and claimed subject matter unless otherwise claimed. No language in the specification should be construed as indicating any non-claimed element as essential to the practice of the disclosed and claimed subject matter.

Preferred embodiments of this disclosed and claimed subject matter are described herein, including the best mode known to the inventors for carrying out the disclosed and claimed subject matter. Variations of those preferred embodiments may become apparent to those of ordinary skill in the art upon reading the foregoing description. The inventors expect skilled artisans to employ such variations as appropriate, and the inventors intend for the disclosed and claimed subject matter to be practiced otherwise than as specifically described herein. Accordingly, this disclosed and claimed subject matter includes all modifications and equivalents of the subject matter recited in the claims appended hereto as permitted by applicable law. Moreover, any combination of the above-described elements in all possible variations thereof is encompassed by the disclosed and claimed subject matter unless otherwise indicated herein or otherwise clearly contradicted by context.

The disclosed and claimed subject matter relates generally to compositions useful for the selective removal of titanium nitride and molybdenum metal from a microelectronic device having such material(s) thereon during its manufacture. The compositions disclosed herein are capable of removing both titanium nitride and molybdenum metal at rates that can be varied based on the particular need.

For ease of reference, “microelectronic device” corresponds to semiconductor substrates, flat panel displays, phase change memory devices, solar panels and other products including solar cell devices, photovoltaics, and microelectromechanical systems (MEMS), manufactured for use in microelectronic, integrated circuit, energy collection, or computer chip applications. It is to be understood that the terms “microelectronic device,” “microelectronic substrate” and “microelectronic device structure” are not meant to be limiting in any way and include any substrate or structure that will eventually become a microelectronic device or microelectronic assembly. The microelectronic device can be patterned, blanketed, a control and/or a test device.

“Hardmask capping layer” or “hardmask” as used herein corresponds to materials deposited over dielectric material to protect same during the plasma etch step. Hardmask capping layers are traditionally silicon nitrides, silicon oxynitrides, titanium nitride, titanium oxynitride, titanium and other similar compounds.

As used herein, “titanium nitride” and “TiNₓ” correspond to pure titanium nitride as well as impure titanium nitride including varying stoichiometries, and oxygen content (TiOₓN_{y}).

As defined herein, “low-k dielectric material” corresponds to any material used as a dielectric material in a layered microelectronic device, wherein the material has a dielectric constant less than about 3.5. Preferably, the low-k dielectric materials include low-polarity materials such as silicon-containing organic polymers, silicon-containing hybrid organic/inorganic materials, organosilicate glass (OSG), TEOS, fluorinated silicate glass (FSG), silicon dioxide, and carbon-doped oxide (CDO) glass. It is to be appreciated that the low-k dielectric materials may have varying densities and varying porosities.

As defined herein, “metal conductor layers” include copper, tungsten, cobalt, molybdenum, aluminum, ruthenium, alloys including the same, and combinations thereof.

As defined herein, the term “barrier material” corresponds to any material used in the art to seal the metal lines, e.g., copper interconnects, to minimize the diffusion of said metal, e.g., copper, into the dielectric material. Preferred barrier layer materials include tantalum, titanium, ruthenium, hafnium, and other refractory metals and their nitrides and silicides.

“Substantially free” is defined herein as less than 2 wt %, preferably less than 1 wt %, more preferably less than 0.5 wt %, and most preferably less than 0.1 wt %. “Substantially free” also includes 0.0 wt %. The term “free of” means 0.0 wt %.

As used herein, “about” or “approximately” is intended to correspond to +5% of the stated value.

As used herein, “fluoride” species correspond to species including an ionic fluoride (F⁻) or covalently bonded fluoride. It is to be appreciated that the fluoride species may be included as a fluoride species or generated in situ.

As used herein, “chloride” species correspond to species including an ionic chloride (Cl⁻), with the proviso that surfactants that include chloride anions are not considered “chlorides” according to this definition.

Compositions of the disclosed and claimed subject matter may be embodied in a wide variety of specific formulations, as hereinafter more fully described.

In all such compositions, wherein specific components of the composition are discussed in reference to weight percentage ranges including a zero lower limit, it will be understood that such components may be present or absent in various specific embodiments of the composition, and that in instances where such components are present, they may be present at concentrations as low as 0.001 weight percent, based on the total weight of the composition in which such components are employed.

Disclosed herein are etching compositions suitable for etching titanium nitride and molybdenum from a microelectronic device, wherein the etching compositions include, consist essentially of, or consist of, in effective amounts: water; HNO₃; optionally, at least one chloride ion source selected from the group of NH₄Cl and HCl; a base selected from the group of an alkanolamine, NH₄OH, a quaternary ammonium hydroxide, and mixtures thereof, optionally, at least one fluoride ion source; optionally, at least one heteroaromatic compound; and optionally, at least one water-miscible solvent selected from the group of diethylene glycol butyl ether, sulfolane and propylene carbonate.

In some embodiments, the etching compositions disclosed herein are formulated to be substantially free of or free of at least one of the following chemical compounds: 4-methylmorpholine N-oxide, trimethylamine N-oxide, peracetic acid, hydrogen peroxide, urea hydrogen peroxide and metal-containing salts.

The role of each component of the compositions disclosed herein will be explained below in greater detail.

Etching Compositions

In one embodiment, the disclosed and claimed subject matter pertains to an etching composition suitable for etching titanium nitride and molybdenum from a microelectronic device that includes
(A) water;
(B) HNO₃;
(C) a base selected from the group of an alkanolamine, NH₄OH and mixtures thereof;
(D) a halogen ion source that is one or more of a chloride ion source and a fluoride ion source.
   In a further aspect, the etching compositions can further (optionally) include one or both of a (E) at least one heteroaromatic compound and (F) at least one water-miscible solvent selected from the group of diethylene glycol butyl ether, sulfolane, and propylene carbonate.

In a further aspect, the etching compositions consist essentially of components A, B, C and D. In another aspect, the etching compositions consist of components A, B, C and D.

In a further aspect, the etching compositions consist essentially of components A, B, C, D and E. In another aspect, the etching compositions consist of components A, B, C, D and E.

In a further aspect, the etching compositions consist essentially of components A, B, C, D and F. In another aspect, the etching compositions consist of components A, B, C, D and F.

In a further aspect, the etching compositions consist essentially of components A, B, C, D, E and F. In another aspect, the etching compositions consist of components A, B, C, D, E and F.

In some embodiments, the halogen ion source is one or more of NH₄Cl, neat HCl, neat HF and neat NH₄F. In one aspect of these embodiments, the halogen ion source includes NH₄Cl. In one aspect of these embodiments, the halogen ion source includes neat HCl. In one aspect of these embodiments, the halogen ion source includes neat HF. In one aspect of these embodiments, the halogen ion source includes neat NH₄F.

In some embodiments, no phosphoric acid is present in the compositions disclosed herein.

A. Water

The etching compositions of the disclosed and claimed subject matter are aqueous-based and, thus, include water. In the disclosed and claimed subject matter, water functions in various ways such as, for example, to dissolve one or more solid components of the composition, as a carrier of the components, as an aid to facilitate the removal of inorganic salts and complexes, as a viscosity modifier of the composition, and as a diluent. Preferably, the water employed in the etching composition is de-ionized water (DIW) water.

In one embodiment, water will constitute about 2% to about 80% or from about 2% to about 86% by wt. of the etching composition. In other embodiments of the disclosed and claimed subject matter includes from about 4% to about 74% or from about 4% to about 76% by wt. of water. In other preferred embodiments of the disclosed and claimed subject matter includes from about 60% to about 75% by wt. of water. The amount of water in the disclosed and claimed compositions may be in any range having any of the lower and upper endpoints selected from the group of 1, 2, 4, 6, 8, 10, 11, 13, 25, 26, 29, 30, 31, 32, 34, 36, 39, 40, 41, 42, 44, 45, 46, 49, 51, 54, 56, 59, 60, 61, 62, 64, 66, 69, 71, 74, 76, 79, 80, 84, 85, 86% by wt. of the etching composition. For examples, the amount of water may range from about 42% to about 46 wt % or from about 39% to about 51 wt % or from about 55% to about 70 wt % or any other combination of lower and upper endpoints. In some embodiments, for example, the amount of water may range from about 10 wt % to about 80 wt %, about 60 wt % to about 70 wt %, about 60 wt % to about 71 wt %, about 60 wt % to about 72 wt %, about 70 wt % to about 80 wt %, about 10 wt % to about 15 wt %, about 88 wt % to about 96 wt %, about 70 wt % to about 95 wt %, about 88 wt % to about 90 wt %, about 90 wt % to about 92 wt %, about 4 wt % to about 5 wt %, about 35 wt % to about 50 wt %, about 44 wt % to about 45 wt %, about 46 wt % to about 48 wt %. Those skilled in the art will recognize that the amounts of water may be varied in and around these ranges and still fall within the scope of the disclosed and claimed subject matter.

Compositions having a large percentage of water may also be referred to herein as “water-rich compositions.” Still other embodiments of the disclosed and claimed subject matter could include water in an amount to achieve the desired weight percent of the other ingredients within the composition.

B. Nitric Acid (HNO₃)

The etching compositions of the disclosed and claimed subject matter include nitric acid. The nitric acid functions primarily as an oxidant to etch titanium nitride. Commercial grade nitric acid can be used. Typically, the commercially available nitric acid is available as 60% to 90% aqueous solutions. In one embodiment electronic grade nitric acid solutions are employed where such electronic grade solutions typically have a particle count below 100 particles/mL, and where the size of the particles is less than or equal to 0.5 microns and metallic ions are present in the acid in the low parts per million to parts per billion level (volume).

In one embodiment, the amount of nitric acid in the compositions is from about 0.5% to about 50% by weight of the composition. In one aspect of this embodiment, the nitric acid in the compositions is from about 1.8% to about 15% by weight of the composition (as a 100% nitric acid composition, i.e., “neat”).

In other embodiments, the amount of HNO₃ in the composition may be any range having any of the lower and upper endpoints selected from the group of 0.1 0.5, 0.7, 1.0, 1.5, 2.0, 2.5, 3.0, 3.5, 4.0, 4.5, 5.0, 5.5, 6.0, 7.0, 8.0, 9.0, 10, 11, 12, 13, 14, 15, 25, 26, 29, 30, 31, 32, 34, 36, 39, 40, 41, 42, 44, 45, 46, 49, and 50% by wt. of the etching composition. In some embodiments, for example, the amount of neat HNO₃ may range between or be about 0.1 wt % to about 1 wt %, about 0.1 wt % to about 2 wt %, about 0.5 wt % to about 15 wt %, about 5 wt %, about 4.8 wt %, about 10 wt %, about 9.6 wt %, about 9 wt % about 1 wt %, about 0.6 wt %, about 12 wt %, about 15 wt %, about 2.0 to about 3.0 wt %, about 2.4 wt %, about 6.0 to about 12.0 wt %, about 6 wt %.

C. Base

The etching compositions disclosed herein also include at least one basic compound (i.e., base) selected from the group of an alkanolamine, NH₄OH, a quaternary ammonium hydroxide, and mixtures thereof. The base functions primarily to control the pH of the composition.

In one embodiment, the base used in the composition is selected from the group of tetraethylammonium hydroxide (TEAH), trimethylphenylammonium hydroxide (TMPAH), tetramethylammonium hydroxide, tetrabutylammonium hydroxide, choline hydroxide, and ammonium hydroxide.

In another embodiment, the base is an alkanolamine. In one aspect of the is embodiment, the preferred alkanolamines include, the lower alkanolamines which are primary, secondary and tertiary having from 1 to 5 carbon atoms. Examples of such alkanolamines include N-methylethanolamine (NMEA), monoethanolamine (MEA), diethanolamine, mono-, di- and triisopropanolamine, 2-(2-aminoethylamino)ethanol, 2-(2-aminoethoxy)ethanol, triethanolamine (TEA), N-ethyl ethanolamine, N,N-dimethylethanolamine, N,N-diethyl ethanolamine, N-methyl diethanolamine, N-ethyl diethanolamine, cyclohexylaminediethanol and mixtures thereof. In some preferred embodiments, the alkanolamine compounds is one or more of triethanolamine (TEA), diethanolamine, N-methyl diethanolamine, diisopropanolamine, monoethanolamine, amino(ethoxy)ethanol (AEE), N-methyl ethanol amine, monoisopropanol amine, cyclohexylaminediethanol, and mixtures thereof.

In another embodiment, the amount of the base (alkanolamine, NH₄OH, quaternary ammonium hydroxide, or mixture thereof) in the composition is from about 1 to about 10% by weight of the composition. In one aspect of this embodiment, the amount of base is from about 1% to about 5% by weight of the composition. In another aspect of this embodiment, the amount of base is from about 1% to about 3% by weight of the composition.

In other embodiments, the amount of the alkanolamine compound (such as, monoethanolamine (MEA), amino(ethoxy)ethanol (AEE) or others and mixtures thereof) when employed in the composition may be within any range having lower and higher endpoints selected from the group of 1, 2, 3, 3.5, 4, 5, 6, 7, 8, 9, 10, 12, 14, 16, 18, 19, 20, 21, 24, 26, 28, and 30 wt %. For example, the amount of amine or alkanolamine in the composition may be from about 1 wt % to about 10 wt % by weight of the composition. In another aspect of this embodiment, the amount of amine or alkanolamine in the composition may be from about 1 to about 8 wt % of the composition. In another aspect of this embodiment, the amount of amine or alkanolamine in the composition may be from about 1 wt % to about 5 wt % of the composition. In another aspect of this embodiment, the amount of amine or alkanolamine in the composition may be from about 1 wt % to about 4 wt % of the composition. In another aspect of this embodiment, the amount of amine or alkanolamine in the composition may be from about 1 wt % to about 3 wt % of the composition. In another aspect of this embodiment, the amount of amine or alkanolamine in the composition may be from about 1 wt % to about 2 wt % of the composition.

In some specific embodiments, the base includes about 1 wt % of amino(ethoxy) ethanol. In some specific embodiments, the base includes about 2 wt % of amino(ethoxy) ethanol. In some specific embodiments, the base includes about 6 wt % of amino(ethoxy) ethanol. In some specific embodiments, the base includes about 7 wt % of amino(ethoxy) ethanol. In some specific embodiments, the base includes about 0.7 wt % of neat NH₄OH. In some specific embodiments, the base includes about 1.5 wt % of neat NH₄OH. In some specific embodiments, the base includes about 2 wt % of neat NH₄OH. In some specific embodiments, the base includes about 40 wt % of NH₄H₂PO₄. In some specific embodiments, the base includes about 45 wt % of NH₄H₂PO₄.

D. Halogen Ion Source

1. Chloride Ion Source

In some embodiments, the etching compositions disclosed herein optionally include at least one chloride ion source. The at least one chloride ion source primarily functions to aid in the etching of the titanium nitride.

The chloride ion source is not particularly limited as long as it is capable of supplying a chloride ion. In some embodiments, the chloride ion source is one or more of hydrohalic acids (such as hydrochloric acid); and chloride salts (such as ammonium chloride (NH₄Cl)), sodium chloride (NaCl), potassium chloride (KCl), calcium chloride (CaCl₂)) and cupric chloride (CuCl₂). These chloride ion sources may be used alone or as a mixture. In one embodiment, the preferred chloride ion sources are HCl and/or NH₄Cl. In one embodiment, the chloride ion source is HCl. In one embodiment, the chloride ion source is NH₄Cl.

In some embodiments, the amount of the chloride ion source, when employed, is present in the compositions in the range of from about 1 wt % to about 35 wt % of the composition. In one aspect of this embodiment, the amount of chloride ion source present in the compositions is from about 1 wt % to about 30 wt % of the composition. In one aspect of this embodiment, the amount of chloride ion source present in the compositions is from about 10 wt % to about 25 wt % of the composition. In another aspect of this embodiment, the amount of chloride ion source present in the compositions is from about 15 wt % to about 20 wt % of the composition. In another aspect of this embodiment, the amount of chloride ion source present in the compositions is from about 15 wt % to about 30 wt % of the composition. In another aspect of this embodiment, the amount of chloride ion source present in the compositions is from about 20 wt % to about 40 wt % of the composition.

In some specific embodiments, the chloride ion source includes about 27 wt % NH₄Cl. In some specific embodiments, the chloride ion source includes about 22.5 wt % NH₄Cl. In some specific embodiments, the chloride ion source includes about 20 wt % NH₄Cl. In some specific embodiments, the chloride ion source includes about 16.5 wt % NH₄Cl. In some specific embodiments, the chloride ion source includes about 2.5 wt % to about 5 wt % NH₄Cl. In some specific embodiments, the chloride ion source includes about 2.5 wt % to about 3.5 wt % NH₄Cl. In some specific embodiments, the chloride ion source includes about 3 wt % to about 30 wt % NH₄Cl.

In some specific embodiments, the chloride ion source includes about 1 wt % neat of HCl. In some specific embodiments, the chloride ion source includes about 2 wt % neat of HCl. In some specific embodiments, the chloride ion source includes about 20 wt % neat of HCl. In some specific embodiments, the chloride ion source includes about 21 wt % neat of HCl. In some specific embodiments, the chloride ion source includes about 3.0 wt % to about 3.5 wt % of neat HCl. In some specific embodiments, the chloride ion source includes about 5.0 wt % to about 5.5 wt % of neat HCl. In some specific embodiments, the chloride ion source includes about 6.5 wt % to about 7.5 wt % of neat HCl. In some specific embodiments, the chloride ion source includes about 1 wt % to about 7.5 wt % of neat HCl. In some specific embodiments, the chloride ion source includes about 1 wt % to about 25 wt % of neat HCl. In some specific embodiments, the chloride ion source includes about 1 wt % to about 21 wt % of neat HCl. In some specific embodiments, the chloride ion source includes about 10 wt % to about 40 wt % of neat HCl. In some specific embodiments, the chloride ion source includes about 20 wt % to about 40 wt % of neat HCl. In some specific embodiments, the chloride ion source includes about 30 wt % to about 40 wt % of neat HCl.

2. Fluoride Ion Source

In some embodiments, the etching compositions of the disclosed and claimed subject matter optionally include at least one fluoride ion source. Fluoride ion functions primarily as an etch promotor for titanium nitride. Exemplary compounds that provide a fluoride ion according to the present disclosure are hydrofluoric acid and salts thereof, ammonium fluoride, quaternary ammonium fluorides such as, for example, tetramethylammonium fluoride and tetrabutylammonium fluoride, fluoroborates, fluoroboric acid, tetrabutylammonium tetrafluoroborate and aluminum hexafluoride. In one embodiment, the preferred fluoride ion sources are HF and/or NH₄F. In one embodiment, the fluoride ion source is HF. In one embodiment, the fluoride ion source is NH₄F.

When HF is the fluoride ion source, commercial grade hydrofluoric acid can be used. Typically, the commercially available hydrofluoric acid is available as 5% to 70% aqueous solutions. In a preferred embodiment, electronic grade HF acid solutions are employed where such electronic grade solutions typically have a particle count below 100 particles/mL and where the size of the particles is less than or equal to 0.5 microns and metallic ions are present in the acid in the low parts per million to parts per billion level (volume).

In some embodiments, the amount of fluoride ion source present in the compositions is from about 0.01% to about 0.25% by weight of the composition. In one aspect of this embodiment, the amount of fluoride ion source present in the compositions is from about 0.02% to about 0.15% by weight of the composition. In one aspect of this embodiment, the amount of fluoride ion source present in the compositions is from about 0.02% to about 0.10% by weight of the composition. In one aspect of this embodiment, the amount of fluoride ion source present in the compositions is from about 0.10% to about 0.12% by weight of the composition. In one aspect of this embodiment, the amount of fluoride ion source present in the compositions is from about 0.01% to about 0.5% by weight of the composition. In one aspect of this embodiment, the amount of fluoride ion source present in the compositions is from about 0.01% to about 1% by weight of the composition. In one aspect of this embodiment, the amount of fluoride ion source present in the compositions is from about 0.01% to about 2% by weight of the composition.

In some specific embodiments, the fluoride ion source includes about 0.025 wt % of neat HF. In some specific embodiments, the fluoride ion source includes about 0.02 wt % of neat HF. In some specific embodiments, the fluoride ion source includes about 0.035 wt % of neat HF. In some specific embodiments, the fluoride ion source includes about 0.05 wt % of neat HF. In some specific embodiments, the fluoride ion source includes about 0.04 wt % of neat HF. In some specific embodiments, the fluoride ion source includes about 0.10 wt % of neat HF. In some specific embodiments, the fluoride ion source includes about 0.12 wt % of neat HF. In some specific embodiments, the fluoride ion source includes about 0.15 wt % of neat HF.

In some specific embodiments, the fluoride ion source includes about 0.02 wt % to about 0.15 wt % of neat NH₄F. In some specific embodiments, the fluoride ion source includes about 0.02 wt % to about 1 wt % of neat NH₄F. In some specific embodiments, the fluoride ion source includes about 0.02 wt % to about 2 wt % of neat NH₄F. In some specific embodiments, the fluoride ion source includes about 0.12 wt % of neat NH₄F.

E. Heteroaromatic Compound (Optional)

In some embodiments, the etching compositions disclosed herein optionally include at least one heteroaromatic compound. The at least one heteroaromatic compound primarily functions as a molybdenum corrosion inhibitor.

In some embodiments, the heteroaromatic compound is preferably a six-membered heteroaromatic ring having one or more nitrogen atoms as one or more heteroatoms constituting the ring. In one aspect of this embodiment, the heteroaromatic compounds include one or more of pyridine compounds each substituted with an amino group-containing substituent, pyrimidine compounds, pyrazine compounds, pyridazine compounds, benzotriazole compounds, pyrazole compounds and 1,3,5-triazine compounds. In another aspect of this embodiment, the heteroaromatic ring may be substituted with a substituent, such as an amino group-containing substituent or an alkyl, aralkyl, aryl, nitro, nitroso, hydroxyl, carboxyl, carbonyl, alkoxy, halogen, azo, cyano, imino, phosphino, thiol or sulfo group or radical.

The above-mentioned pyridine compounds, which are each substituted with an amino group-containing substituent, are not particularly limited as far as the compounds are each a compound having a pyridine ring and substituted with an amino group-containing substituent. In some embodiments, the pyridine compounds are, for example, pyridine compounds each represented by the following Formula (I):

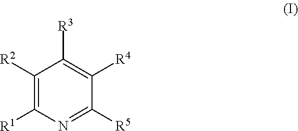

where R¹ to R⁵ each independently represent hydrogen, an amino group-containing substituent, or a hydrocarbon derivation group which is other than any amino group-containing substituent and has 1 to 10 carbon atoms, provided that at least one of R¹ to R⁵ represents the amino group-containing substituent; and these substituents may be bonded to one another to form a cyclic structure.

Specific examples of the pyridine compounds, which are each substituted with an amino group-containing substituent, include 3-aminopyridine, 2-aminopyridine, 4-aminopyridine, 2-amino-3-methylpyridine, 2-amino-4-methylpyridine, 2-amino-5-methylpyridine, 2-(aminomethyl)pyridine, 3-amino-4-methylpyridine, 5-amino-2-methylpyridine, 4-amino-3-methylpyridine, 3-amino-2-methylpyridine, 4-amino-2-methylpyridine, 3-amino-5-methylpyridine, 2-(methylamino)pyridine, 4-(methylamino)pyridine, 3-(aminomethyl)pyridine, 4-(aminomethyl)pyridine, 2,3-diaminopyridine, 3,4-diaminopyridine, 2,6-diaminopyridine, 2-amino-5-cyanopyridine, 2-amino-3-cyanopyridine, 2-aminopyridine-3-carboxyaldehyde, pyridine-2-carboxamide, 2-amino-4,6-dimethylpyridine, 4-(2-aminoethyl)pyridine, 3-(2-aminoethyl)pyridine, 2-(2-aminoethyl)pyridine, 4-dimethylaminopyridine, 2-dimethylaminopyridine, 2-(ethylamino)pyridine, 2-amino-3-(hydroxymethyl)pyridine, 4-acetamidopyridine, 2-acetamidopyridine, 3-acetamidopyridine, 4-(ethylaminomethyl)pyridine, 2-aminoquinoline, 3-aminoquinoline, 5-aminoquinoline, 6-aminoquinoline, 8-aminoquinoline and 4-dimethylamino-1-neopentylpyridinium chloride.

Examples of 6-membered heterocyclic rings that contain one nitrogen atom with at least one additional nitrogen atom binding site not contained in a ring include, but are not limited to: 2-aminopyridine; 2,6-diaminopyridine; 2-(aminomethyl)pyridine; 2,6-(aminomethyl)pyridine; 2,6-(aminoethyl)pyridine; 2-amino-4-picoline; 2,6-diamino-4-picoline; 2-amino-3,5-lutidine; 2-aminoquinoline; 8-aminoquinoline; 2-aminoisoquinoline; acriflavine; 4-aminophenanthridine; 4,5-(aminomethyl)phenothiazine; 4,5-(aminomethyl)dibenzoxazine; 10-amino-7,8-benzoquinoline; bis(2-pyridylmethane)amine; tris(2-pyridyl)amine; bis(4-(2-pyridyl)-3-azabutane)amine; bis(N,N-(2-(2-pyridyl)ethane)aminomethane)amine and 4-(N,N-dialkylaminomethyl)morpholine.

In some embodiments, the heteroatom compound is present in the composition in the range of from about 0.01 wt % to about 3.0 wt % of the composition. In some embodiments, the heteroatom compound is present in the composition in the range of from about 0.01 wt % to about 2.0 wt % of the composition. In some embodiments, the heteroatom compound is present in the composition in the range of from about 0.01 wt % to about 1.0 wt % of the composition. In some embodiments, the heteroatom compound is present in the composition in the range of from about 0.01 wt % to about 0.5 wt % of the composition. In one aspect of this embodiment, the amount of the heteroatom compound is present in the composition in the range of from about 0.01 wt % to about 0.3 wt % of the composition. In another aspect of this embodiment, the amount of the heteroatom compound is present in the composition in the range of from about 0.02 wt % to about 0.1 wt % of the composition.

F. Water-Miscible Solvent (Optional)

The etching compositions of the disclosed and claimed subject matter optionally include at least one water-miscible solvent. The at least one water-miscible solvent functions primarily to reduce Mo etch at lower aqueous media.

Examples of suitable water-miscible solvents include methanol, ethanol, isopropanol, butanol, pentanol, hexanol, 2-ethyl-1-hexanol, heptanol, octanol, ethylene glycol, 1,2- and 1,3-propylene glycol, 1,2-, 1,3-, and 1,4-butanediol, tetrahydrofurfuryl alcohol (THFA), butylene carbonate, ethylene carbonate, propylene carbonate, dipropylene glycol, diethylene glycol monomethyl ether, triethylene glycol monomethyl ether, diethylene glycol monoethyl ether, triethylene glycol monoethyl ether, ethylene glycol monopropyl ether, ethylene glycol monobutyl ether, diethylene glycol monobutyl ether, triethylene glycol monobutyl ether, ethylene glycol monohexyl ether, diethylene glycol monohexyl ether, ethylene glycol phenyl ether, propylene glycol methyl ether, dipropylene glycol methyl ether (DPGME), tripropylene glycol methyl ether (TPGME), dipropylene glycol dimethyl ether, dipropylene glycol ethyl ether, propylene glycol n-propyl ether, dipropylene glycol n-propyl ether (DPGPE), tripropylene glycol n-propyl ether, propylene glycol n-butyl ether, dipropylene glycol n-butyl ether, tripropylene glycol n-butyl ether, propylene glycol phenyl ether, 2,3-dihydrodecafluoropentane, ethyl perfluorobutylether, methyl perfluorobutylether, alkyl carbonates, alkylene carbonates, 4-methyl-2-pentanol, tetramethylene glycol dimethyl ether, dimethyl sulfoxide, sulfolane, and combinations thereof.

In some embodiments, the at least one water-miscible solvent is selected from the group of sulfolane, diethylene glycol monoethyl ether, diethylene glycol butyl ether, propylene carbonate, diethylene glycol methyl ether, propylene glycol, ethylene glycol, tetraethylene glycol dimethyl ether, triethylene glycol methyl ether, triethylene glycol ethyl ether, tripropylene glycol monomethyl ether, dipropylene glycol monomethyl ether, and combinations thereof.

In some embodiments, the at least one water-miscible solvent is selected from the group of sulfolane, diethylene glycol butyl ether, propylene carbonate, and mixtures thereof.

In some embodiments, the at least one water-miscible solvent is present in the composition in the range of from about 40% to about 99% by weight of the composition. In some embodiments, the at least one water-miscible solvent is present in the composition in the range of from about 50% to about 99% by weight of the composition. In some embodiments, the at least one water-miscible solvent is present in the composition in the range of from about 40% to about 75% by weight of the composition. In some embodiments, the at least one water-miscible solvent is present in the composition in the range of from about 50% to about 75% by weight of the composition. In one aspect of this embodiment, the at least one water-miscible solvent is present in the composition in the range of from about 70% to about 93% by weight of the composition.

Other Optional Ingredients

In some embodiments the disclosed and claimed etching composition may also include one or more metal chelating agents. Metal chelating agents can function to increase the capacity of the composition to retain metals in solution and to enhance the dissolution of metallic residues. Typical examples of chelating agents useful for this purpose are the following organic acids and their isomers and salts: ethylenediaminetetraacetic acid (EDTA), butylenediaminetetraacetic acid, (1,2-cyclohexylenediamine)tetraacetic acid (CyDTA), diethylenetriaminepentaacetic acid (DETPA), ethylenediaminetetrapropionic acid, (hydroxyethyl)ethylenediaminetriacetic acid (HEDTA), N, N,N′, N′-ethylenediaminetetra(methylenephosphonic) acid (EDTMP), triethylenetetraminehexaacetic acid (TTHA), 1,3-diamino-2-hydroxypropane-N,N,N′,N′-tetraacetic acid (DHPTA), methyliminodiacetic acid, propylenediaminetetraacetic acid, nitrotriacetic acid (NTA), acetic acid, citric acid, tartaric acid, gluconic acid, saccharic acid, glyceric acid, oxalic acid, phthalic acid, maleic acid, mandelic acid, malonic acid, lactic acid, salicylic acid, propyl gallate, pyrogallol, 8-hydroxyquinoline, and cysteine. Preferred chelating agents are aminocarboxylic acids such as EDTA, CyDTA and aminophosphonic acids such as EDTMP.

In some embodiments, the chelating agent is present in the composition in the range of from about 0.1 wt % to about 10 wt %. In one aspect of this embodiment, the chelating agent is present in the composition in the range of from about 0.5 wt % to about 5 wt % of the composition.

In some embodiments the compositions of this disclosed and claimed subject matter will be free of or substantially free of any or all of the above-listed chelating agents added to the composition.

Highlighted Formulations

In one preferred embodiment, the etching composition includes
(a) about 10 wt % to about 80 wt % water;
(b) about 0.5 wt % to about 15 wt % neat HNO₃;
(c) a base that includes one or more of:
   (i) about 1 wt % to about 7 wt % of one or more alkanolamine, and
   (ii) about 0.7 wt % to about 2 wt % of neat NH₄OH; and
(d) a halogen ion source that includes one or more of:
   (i) about 1 wt % to about 30 wt % of one or more chloride ion source, and
   (ii) about 0.02 wt % to about 0.15 wt % of one or more fluoride ion source.
      In one aspect of this embodiment, the base includes about 1 wt % to about 7 wt % of alkanolamine. In another aspect of this embodiment, the base includes about 0.7 wt % to about 2 wt % of neat NH₄OH.

In another preferred embodiment, the etching composition includes
(a) about 10 wt % to about 80 wt % water;
(b) about 0.5 wt % to about 15 wt % neat HNO₃;
(c) a base that includes one or more of:
   (i) about 1 wt % to about 7 wt % of one or more alkanolamine, and
   (ii) about 0.7 wt % to about 2 wt % of neat NH₄OH; and
(d) a halogen ion source that includes one or more of:
   (i) about 3 wt % to about 30 wt % NH₄Cl,
   (ii) about 1 wt % to about 25 wt % of neat HCl,
   (iii) about 0.02 wt % to about 0.15 wt % of neat HF, and
   (iv) about 0.02 wt % to about 0.15 wt % of neat NH₄F.
      In one aspect of this embodiment, the etching composition includes about 3 wt % to about 30 wt % NH₄Cl. In another aspect of this embodiment, the etching composition includes about 1 wt % to about 25 wt % of neat HCl. In another aspect of this embodiment, the etching composition includes about 0.02 wt % to about 0.15 wt % of neat HF. In another aspect of this embodiment, the etching composition includes about 0.02 wt % to about 0.15 wt % of neat NH₄F.

In another preferred embodiment, the etching composition includes
(a) about 10 wt % to about 80 wt % water;
(b) about 0.5 wt % to about 15 wt % neat HNO₃;
(c) a base that includes one or more of:
   (i) about 1 wt % to about 7 wt % of one or more alkanolamine, and
   (ii) about 0.7 wt % to about 2 wt % of neat NH₄OH; and
(d) a halogen ion source that includes one or more of:
   (i) about 3 wt % to about 30 wt % NH₄Cl,
   (ii) about 1 wt % to about 21 wt % of neat HCl,
   (iii) about 0.02 wt % to about 0.15 wt % of neat HF, and
   (iv) about 0.02 wt % to about 0.15 wt % of neat NH₄F.
      In one aspect of this embodiment, the etching composition includes about 3 wt % to about 30 wt % NH₄Cl. In another aspect of this embodiment, the etching composition includes about 1 wt % to about 21 wt % of neat HCl. In another aspect of this embodiment, the etching composition includes about 0.02 wt % to about 0.15 wt % of neat HF. In another aspect of this embodiment, the etching composition includes about 0.02 wt % to about 0.15 wt % of neat NH₄F.

In another preferred embodiment, the etching composition includes
(a) about 35 wt % to about 80 wt % water;
(b) about 0.1 wt % to about 5 wt % neat HNO₃;
(c) a base that includes one or more of:
   (i) about 1 wt % to about 7 wt % of one or more alkanolamine, and
   (ii) about 0.7 wt % to about 2 wt % of neat NH₄OH; and
(d) a halogen ion source that includes one or more of:
   (i) about 3 wt % to about 30 wt % NH₄Cl,
   (ii) about 1 wt % to about 21 wt % of neat HCl,
   (iii) about 0.02 wt % to about 0.15 wt % of neat HF, and
   (iv) about 0.02 wt % to about 0.15 wt % of neat NH₄F.
      In one aspect of this embodiment, the etching composition includes about 3 wt % to about 30 wt % NH₄Cl. In another aspect of this embodiment, the etching composition includes about 1 wt % to about 21 wt % of neat HCl. In another aspect of this embodiment, the etching composition includes about 0.02 wt % to about 0.15 wt % of neat HF. In another aspect of this embodiment, the etching composition includes about 0.02 wt % to about 0.15 wt % of neat NH₄F.

In another preferred embodiment, the etching composition includes
(a) about 60 wt % to about 70 wt % water;
(b) about 4.8 wt % of neat HNO₃;
(c) a base including about 1 wt % of amino(ethoxy) ethanol; and
(d) a halogen ion source including
   (i) about 27 wt % NH₄Cl,
   (ii) about 2.1 wt % neat of HCl, and
   (iii) about 0.025 wt % of neat HF.

In another preferred embodiment, the etching composition includes
(a) about 60 wt % to about 71 wt % water;
(b) about 4.8 wt % of neat HNO₃;
(c) a base including about 1 wt % of amino(ethoxy) ethanol; and
(d) a halogen ion source including
   (i) about 22.5 wt % NH₄Cl;
   (ii) about 1.05 wt % of neat HCl; and
   (iii) about 0.025 wt % of neat HF.

In another preferred embodiment, the etching composition includes
(a) about 60 wt % to about 72 wt % water;
(b) about 9.6 wt % of neat HNO₃;
(c) a base including about 2 wt % of amino(ethoxy) ethanol; and
(d) a halogen ion source including
   (i) about 16.5 wt % NH₄Cl; and
   (ii) about 0.02 wt % of neat HF.

In another preferred embodiment, the etching composition includes
(a) about 60 wt % to about 70 wt % water;
(b) about 9.6 wt % of neat HNO₃;
(c) a base including about 2 wt % of amino(ethoxy) ethanol; and
(d) a halogen ion source including
   (i) about 20 wt % NH₄Cl; and
   (ii) about 0.035 wt % of neat HF.

In another preferred embodiment, the etching composition includes
(a) about 60 wt % to about 70 wt % water;
(b) about 9.6 wt % of neat HNO₃;
(c) a base including about 0.7 wt % of neat NH₄OH; and
(d) a halogen ion source including
   (i) about 20 wt % NH₄Cl; and
   (ii) about 0.035 wt % of neat HF.

In another preferred embodiment, the etching composition includes
(a) about 70 wt % to about 80 wt % water;
(b) about 0.6 wt % of neat HNO₃;
(c) a base including about 1.45 wt % of neat NH₄OH; and
(d) a halogen ion source including
   (i) about 21 wt % neat HCl; and
   (ii) about 0.12 wt % of neat NH₄F.

In another preferred embodiment, the etching composition includes
(a) about 10 wt % to about 15 wt % water;
(b) about 4.8 wt % of neat HNO₃;
(c) a base including about 7 wt % of amino(ethoxy) ethanol;
(d) a halogen ion source including about 0.05 wt % of neat HF; and
(e) about 75 wt % of neat acetic acid.

In another preferred embodiment, the etching composition includes
(a) about 10 wt % to about 15 wt % water;
(b) about 4.8 wt % of neat HNO₃;
(c) a base including about 6 wt % of amino(ethoxy) ethanol;
(d) a halogen ion source including about 0.05 wt % of neat HF; and
(e) about 76 wt % of neat acetic acid.

In another preferred embodiment, the etching composition includes
(a) about 10 wt % to about 15 wt % water;
(b) about 4.8 wt % of neat HNO₃;
(c) a base including about 6 wt % of amino(ethoxy) ethanol;
(d) a halogen ion source including about 0.04 wt % of neat HF; and
(e) about 78 wt % of neat acetic acid.

In another preferred embodiment, the etching composition includes
(a) about 10 wt % to about 15 wt % water;
(b) about 9 wt % of neat HNO₃;
(c) a base including about 2.03 wt % of neat NH₄OH;
(d) a halogen ion source including about 0.05 wt % of neat HF; and
(e) about 77 wt % of sulfolone.

In another preferred embodiment, the etching composition includes
(a) about 88 wt % to about 96 wt % water;
(b) about 2 wt % to about 15 wt % of neat HNO₃;
(c) a halogen ion source including about 0.02 wt % to about 0.10 wt % of one or more fluoride ion source;
(d) about 70 wt % to about 95 wt % of one or more water-miscible solvents selected from diethyl glycol butyl ether, sulfolane and propylene carbonate.
   In another aspect of this embodiment, the etching composition includes about 0.02 wt % to about 0.10 wt % of neat HF. In another aspect of this embodiment, the etching composition includes about 0.05 of neat HF. In another aspect of this embodiment, the etching composition includes about 70 wt % to about 80 wt % of diethyl glycol butyl ether. In another aspect of this embodiment, the etching composition includes about 70 wt % to about 80 wt % of sulfolane. In another aspect of this embodiment, the etching composition includes about 85 wt % to about 95 wt % of propylene carbonate. In another aspect of this embodiment, the etching composition further includes 8-aminoquinoline. In another aspect of this embodiment, the etching composition further includes triethanolamine.

In another preferred embodiment, the etching composition includes
(a) about 90 wt % to about 92 wt % water;
(b) about 12 wt % of neat HNO₃;
(c) a halogen ion source including about 0.05 wt % of HF;
(d) about 79 wt % of diethyl glycol butyl ether.

In another preferred embodiment, the etching composition includes
(a) about 88 wt % to about 90 wt % water;
(b) about 15 wt % of neat HNO₃;
(c) a halogen ion source including about 0.05 wt % of HF;
(d) about 74 wt % of diethyl glycol butyl ether; and
(e) about 0.05 wt % of 8-aminoquinoline.

In another preferred embodiment, the etching composition includes
(a) about 4 wt % to about 5 wt % water;
(b) about 2.0 to about 3.0 wt % of neat HNO₃;
(c) a halogen ion source including about 0.10 wt % to about 0.12 wt % of HF;
(d) about 90 wt % to about 93 wt % of propylene carbonate; and
(e) about 0.4 wt % to about 0.6 wt % of triethanolamine.

In another preferred embodiment, the etching composition includes
(a) about 4 wt % to about 5 wt % water;
(b) about 2.4 of neat HNO₃;
(c) a halogen ion source including about 0.12 wt % of HF;
(d) about 92 wt % to about 93 wt % of propylene carbonate; and
(e) about 0.6 wt % of triethanolamine.

In another preferred embodiment, the etching composition includes
(a) about 35 wt % to about 50 wt % water;
(b) about 6.0 to about 12.0 wt % of neat HNO₃;
(c) a base including about 15 wt % to about 45 wt % of NH₄H₂PO₄; and
(d) a halogen ion source including one or more of
   (i) about 1 wt % to about 7.5 wt % of neat HCl and
   (ii) about 2.5 wt % to about 5 wt % NH₄Cl.

In another preferred embodiment, the etching composition includes
(a) about 44 wt % to about 45 wt % water;
(b) about 12.0 wt % of neat HNO₃;
(c) a base including about 40 wt % of NH₄H₂PO₄; and
(d) a halogen ion source including about 3.0 wt % to about 3.5 wt % of neat HCl.

In another preferred embodiment, the etching composition includes
(a) about 46 wt % to about 48 wt % water;
(b) about 6.0 wt % of neat HNO₃;
(c) a base including about 40 wt % of NH₄H₂PO₄; and
(d) a halogen ion source including about 6.5 wt % to about 7.5 wt % of neat HCl.

In another preferred embodiment, the etching composition includes
(a) about 46 wt % to about 48 wt % water;
(b) about 9.0 wt % of neat HNO₃;
(c) a base including about 45 wt % of NH₄H₂PO₄; and
(d) a halogen ion source including
   (i) about 5 wt % to about 5.5 wt % of neat HCl and
   (ii) about 2.5 wt % to about 3.5 wt % NH₄Cl.

The disclosed and claimed compositions are not are not limited to those exemplified and described above.

Method of Use

In another aspect of the disclosed and claimed subject there is provided a method of selectively enhancing the etch rate of titanium nitride and molybdenum on a composite semiconductor device including titanium nitride and molybdenum. The method includes the steps of:
a. contacting the composite semiconductor device including titanium nitride and molybdenum with a composition which includes, consists essentially of, or consists of: any of the compositions described above, such as for example one including water; HNO₃; optionally, at least one chloride ion source selected from the group of NH₄Cl and HCl; a base selected from the group of an alkanolamine, NH₄OH, a quaternary ammonium hydroxide and mixtures thereof; optionally, at least one fluoride ion source; at least one heteroaromatic compound; and optionally, a solvent selected from the group of diethylene glycol butyl ether, sulfolane and propylene carbonate; and
b. rinsing the composite semiconductor device after the titanium nitride and molybdenum is at least partially removed.

An additional drying step c. may also be included in the method. “At least partially removed” means removal of at least 90% of the material, preferably at least 95% removal. Most preferably, at least 99% removal using the compositions of the present development. In other embodiments, performing the above method with the compositions disclosed herein selectively etches titanium nitride over molybdenum metal at a ratio of from 1:3 to 15.1:1.

The contacting step can be carried out by any suitable means such as, for example, immersion, spray, or via a single wafer process. The temperature of the composition during the contacting step is preferably from about 20 to 80° C. and more preferably from about 40 to 70° C. Even more preferably, the temperature of the composition during the contacting step is about 60° C.

The rinsing step is carried out by any suitable means, for example, rinsing the substrate with de-ionized water by immersion or spray techniques. In preferred embodiments, the rinsing step is carried out employing a mixture of de-ionized water and a water-miscible organic solvent such as, for example, isopropyl alcohol.

The drying step is carried out by any suitable means, for example, isopropyl alcohol (IPA) vapor drying, heat, by centripetal force, or nitrogen flow.

The features and advantages are more fully shown by the illustrative examples discussed below.

Reference will now be made to more specific embodiments of the present disclosure and experimental results that provide support for such embodiments. The examples are given below to more fully illustrate the disclosed subject matter and should not be construed as limiting the disclosed subject matter in any way.

It will be apparent to those skilled in the art that various modifications and variations can be made in the disclosed subject matter and specific examples provided herein without departing from the spirit or scope of the disclosed subject matter. Thus, it is intended that the disclosed subject matter, including the descriptions provided by the following examples, covers the modifications and variations of the disclosed subject matter that come within the scope of any claims and their equivalents.

### Examples

General Procedure for Preparing the Etching Compositions

The etching solution composition of the disclosed and claimed subject matter is typically prepared by mixing the components together in a vessel at room temperature until all solids have dissolved in the aqueous-based medium. For example, all compositions which are the subject of the present Examples were prepared by mixing the components in a 250 mL beaker with a 1″ Teflon-coated stir bar. Typically, the first material added to the beaker was deionized (DI) water.

Compositions of the Substrate

Each test 20 mm×20 mm coupon employed in the present examples includes a layer of titanium nitride, and a layer of molybdenum on a silicon substrate. There are two separated substrates.

Processing Conditions

Etching tests were run using 100 g of the etching compositions in a 250 ml beaker with a 1″ Teflon® stir bar set at 500 rpm. The etching compositions were heated to a temperature of about 60° C. on a hot plate. The test coupons were immersed in the compositions for about 100 sec or 3 or 5 minutes while stirring. The segments were then rinsed for 3 minutes in a DI water bath or spray and subsequently dried using filtered nitrogen. The titanium nitride and molybdenum etch rates were estimated from changes in the thickness before and after etching and was measured by 4-point probe. (CDE ResMap Control, America). Typical starting layer thickness was 300 Å for TiNₓ and 200 Å for molybdenum.

The following series of Tables show the evaluation of several aspects of the compositions evaluated. In the table, values in parentheses are neat wt % values.

TABLE 1
Non-fluoride Formulations with Phosphoric Buffer

| Raw Material | 146P | 148E | 50N | 50N |
|---|---|---|---|---|
| HNO₃ (60%) | 10 (6) | 20 (12) | 10 (6) | 10 (6) |
| DIW | 40 | 30 | 30 | 30 |
| H₃PO₄ (85%) | 35 (29.75) | 0 | 0 | 0 |
| NH₄H₂PO₄ | 15 | 40 | 40 | 40 |
| HCl (35%) | 0 | 10 (3.5) | 20 (7) | 20 (7) |
| Total | 100 | | | |
| Temperature (° C.) | 60 | | | 70 |
| TiN E/R (Å/min) | 2.13 | 2.42 | 2.26 | 4.81 |
| 5 min | | | | |
| Mo E/R (Å/min) | 4.5 | 6.36 | 1.06 | 1.3 |
| 5 min | | | | |

Table 1 illustrates that using HNO₃ as an oxidant and H₃PO₄/NH₁₄H₂PO₄ as a buffer system gives 1:2 ratio of TiN/Mo etch rate selectivity. Optional HCl and NH₄H₂PO₄ mixture can generate H₃PO₄/NH₄H₂PO₄/NH₄Cl which give similar result. By reducing HNO₃ and increasing HCl can give >1 selectivity of TiN to Mo etch rate due to more chloride effect. Higher temperature can increase selectivity of TiN to Mo etch rate.

TABLE 2
Non-fluoride Formulations with Ammonium Chloride

| Raw Material | 48V | 53T | 54E | 53J |
|---|---|---|---|---|
| HNO₃ (60%) | 15 (9) | 8 (4.8) | 8 (4.8) | 10 (6) |
| DIW | 22 | 64 | 63 | 55 |
| NH₄H₂PO₄ | 45 | 0 | 0 | 0 |
| NH₄Cl | 3 | 24 | 24 | 30 |
| HCl (35%) | 15 (5.25) | 4 (1.4) | 5 (1.75) | 5 (1.75) |
| Total | 100 | | | |
| Temperature (° C.) | 60 | | | |
| TiN E/R (Å/min) | 3.72 | 5.54 | 5.55 | 5.02 |
| 5 min | | | | |
| Mo E/R (Å/min) | 1.42 | 4.57 | 5.93 | 13.68 |
| 5 min | | | | |

Table demonstrates that by adding NH₄Cl as a chloride source, 48V provides NH₄H₂PO₄/NH₄Cl/HCl system and give good TiN/Mo selectivity. To simplify the formulation, NH₄H₂PO₄ can be removed to slightly enhance TiN etch rate by NH₄Cl/HCl system.

TABLE 3
Fluoride Formulations with Ammonium Chloride

| Raw Material | 57C | | 57H | | 58L | | 60G | | 61Q | | 33J | |
|---|---|---|---|---|---|---|---|---|---|---|---|---|
| HNO₃ (60%) | 8 | (4.8) | 8 | (4.8) | 16 | (9.6) | 16 | (9.6) | 16 | (9.6) | 1 | (0.6) |

| DIW | 57.5 | 65.0 | 65.2 | 61.3 | 60.9 | | 33.7 | |
|---|---|---|---|---|---|---|---|---|
| NH₄Cl | 27 | 22.5 | 16.5 | 20 | 20 | | 0 | |
| NH₄F (40%) | 0 | 0 | 0 | 0 | 0 | | 0.3 | (0.12) |
| AEE | 1 | 1 | 2 | 2 | 0 | | 0 | |
| NH₄OH (29%) | 0 | 0 | 0 | 0 | 2.4 | (0.7) | 5 | (1.45) |

| | | | | | | | | | | | |
|---|---|---|---|---|---|---|---|---|---|---|---|
| HF (5%) | 0.5 | (0.025) | 0.5 | (0.025) | 0.4 | (0.02) | 0.7 | (0.035) | 0.7 | (0.035) | 0 |

| | | | | | | | | | |
|---|---|---|---|---|---|---|---|---|---|
| HCl (35%) | 6 | (2.1) | 3.0 | (1.05) | 0 | 0 | 0 | 60 | (21) |

| Total | 100 | | | | | |
|---|---|---|---|---|---|---|
| Temperature (° C.) | 60 | | | | | 50 |
| TiN E/R (Å/min) 100 sec | 46.83 | 30.2 | 65.71 | 73.67 | 49.29 | 37.3 |
| Mo E/R (Å/min) 100 sec | 12.83 | 2 | 6.86 | 6.71 | 22.65 | 38.7 |

Example 57C employed a NH₄Cl/HCl system with small amounts of HF (<0.10) which can boost the TiN etch rate from 5 to 46 A/min. Example 58L reduced the amount of NH₄Cl from 27% to 16% and increased the amount of HNO₃ which gave good TiN/Mo E/R selectivity. 61Q replaced the base component from ALE to NH₄OH, which also showed good TiN/Mo E/R selectivity. Example, 33J exhibited a Mo/TiN etch rate selectivity 1:1 at 50° C., when coupled.

TABLE 4
Acetic Acid Based Formulations

| Raw Material | 63N | 63Q | 63R |
|---|---|---|---|
| HNO₃ (60%) | 8.0 (4.8) | 8.0 (4.8) | 8.0 (4.8) |
| AEE | 7 | 6 | 6 |
| Acetic Acid (neat) | 75 | 76 | 78 |
| HF (0.5%) | 10.0 (0.05) | 10.0 (0.05) | 8.0 (0.04) |
| Total | 100 | | |
| Temperature (° C.) | 60 | | |
| TiN E/R (Å/min) | 24.5 | 38.9 | 39 |
| 100 sec | | | |
| Mo E/R (Å/min) | 11.9 | 9 | 25 |
| 100 sec | | | |

Table 4 shows acetic acid as both a weak acid having proper pH to suppress Mo E/R and also as a solvent in examples 63N, 63Q and 63R. HNO₃ is an oxidant and HF is an etch promotor that can provide good TiN/Mo selectivity.

TABLE 5
Formulations with Different Solvents

| Raw Material | 64L | 64X | 64O | 70I |
|---|---|---|---|---|
| HNO₃ (60%) | 20 (12) | 25 (15) | 15 (9) | 4 (2.4) |
| NH₄OH (29%) | 0 | 0 | 7 (2.03) | 0 |
| Triethanolamine | 0 | 0 | 0 | 0.6 |
| 8-Aminoquinoline | 0 | 0.05 | 0 | 0 |
| Sulfolane | 0 | 0 | 77 | 0 |
| BDG | 79 | 74 | 0 | 0 |
| PC | 0 | 0 | 0 | 92.6 |
| HF (5%) | 1 (0.05) | 1 (0.05) | 1 (0.05) | 2.8 (0.12) |
| Total | 100 | | | |
| Temperature (° C.) | 60 | | | |
| TiN E/R (Å/min) | 28.87 | 40.32 | 34.02 | 26.35 |
| 100 sec | | | | |
| Mo E/R (Å/min) | 30.65 | 22.56 | 14.87 | 2.79 |
| 100 sec | | | | |

Table 5 shows that solvent rich formulations that included diethyl glycol butyl ether (BDG), sulfolane, and propylene carbonate (PC) can eliminate NH₄Cl with HNO₃/HF activate combination. 8-aminoquinoline can be a Mo corrosion inhibitor to suppress Mo E/R.

The foregoing description is intended primarily for purposes of illustration. Although the disclosed and claimed subject matter has been shown and described with respect to an exemplary embodiment thereof, it should be understood by those skilled in the art that the foregoing and various other changes, omissions, and additions in the form and detail thereof may be made therein without departing from the spirit and scope of the disclosed and claimed subject matter.

1. An etching composition suitable for the removal of titanium nitride and molybdenum from a microelectronic device, comprising
(a) about 10 wt % to about 80 wt % water;
(b) about 0.5 wt % to about 15 wt % neat HNO₃;
(c) a base comprising one or more of
(i) about 1 wt % to about 7 wt % of one or more alkanolamine; and
(ii) about 0.7 wt % to about 2 wt % of neat NH₄OH; and
(d) a halogen ion source comprising one or more of
(i) about 1 wt % to about 30 wt % of one or more chloride ion source; and
(ii) about 0.02 wt % to about 0.15 wt % of one or more fluoride ion source.

2. The etching composition of claim 1, wherein the halogen ion source one or more of:
(i) about 3 wt % to about 30 wt % NH₄Cl;
(ii) about 1 wt % to about 25 wt % of neat HCl;
(iii) about 0.02 wt % to about 0.15 wt % of neat HF; and
(iv) about 0.02 wt % to about 0.15 wt % of neat NH₄F.

3. The etching composition of claim 1, wherein the base comprises about 1 wt % to about 7 wt % of alkanolamine.

4. The etching composition of claim 1, wherein the base comprises about 0.7 wt % to about 2 wt % of neat NH₄OH.

5-8. (canceled)

9. The etching composition of claim 1, wherein the base is one or more alkanolamine selected from the group of N-methylethanolamine (NMEA), monoethanolamine (MEA), diethanolamine, mono-, di- and triisopropanolamine, 2-(2-aminoethylamino)ethanol, 2-(2-aminoethoxy)ethanol, triethanolamine, N-ethyl ethanolamine, N,N-dimethylethanolamine, N,N-diethyl ethanolamine, N-methyl diethanolamine, N-ethyl diethanolamine, cyclohexylaminediethanol, and mixtures thereof.

10. (canceled)

11. The etching composition of claim 1, wherein the base comprises amino(ethoxy) ethanol.

12. The etching composition of claim 1 further comprising about 70 wt % and about 80 wt % of neat acetic acid.

13. The etching composition of claim 1 further comprising at least one heteroaromatic compound.

14-18. (canceled)

19. The etching composition of claim 1 further comprising at least one water-miscible solvent selected from the group of diethylene glycol butyl ether, sulfolane, and propylene carbonate.

20-22. (canceled)

23. The etching composition of claim 1 further comprising (i) 8-aminoquinoline and (ii) at least one water-miscible solvent selected from the group of diethylene glycol butyl ether, sulfolane and propylene carbonate.

24. (canceled)

25. The etching composition of claim 1, wherein the composition comprises
(a) about 60 wt % to about 70 wt % water;
(b) about 4.8 wt % of neat HNO₃;
(c) a base comprising about 1 wt % of amino(ethoxy) ethanol; and
(d) a halogen ion source comprising
(i) about 27 wt % NH₄Cl;
(ii) about 2.1 wt % neat of HCl; and
(iii) about 0.025 wt % of neat HF.

26. The etching composition of claim 1, wherein the composition comprises
(a) about 60 wt % to about 71 wt % water;
(b) about 4.8 wt % of neat HNO₃;
(c) a base comprising about 1 wt % of amino(ethoxy) ethanol; and
(d) a halogen ion source comprising
(i) about 22.5 wt % NH₄Cl;
(ii) about 1.05 wt % of neat HCl; and
(iii) about 0.025 wt % of neat HF.

27. The etching composition of claim 1, wherein the composition comprises
(a) about 60 wt % to about 72 wt % water;
(b) about 9.6 wt % of neat HNO₃;
(c) a base comprising about 2 wt % of amino(ethoxy) ethanol; and
(d) a halogen ion source comprising
(i) about 16.5 wt % NH₄Cl; and
(ii) about 0.02 wt % of neat HF.

28. The etching composition of claim 1, wherein the composition comprises
(a) about 60 wt % to about 70 wt % water;
(b) about 9.6 wt % of neat HNO₃;
(c) a base comprising about 2 wt % of amino(ethoxy) ethanol; and
(d) a halogen ion source comprising
(i) about 20 wt % NH₄Cl; and
(ii) about 0.035 wt % of neat HF.

29. The etching composition of claim 1, wherein the composition comprises
(a) about 60 wt % to about 70 wt % water;
(b) about 9.6 wt % of neat HNO₃;
(c) a base comprising about 0.7 wt % of neat NH₄OH; and
(d) a halogen ion source comprising
(i) about 20 wt % NH₄Cl; and
(ii) about 0.035 wt % of neat HF.

30. The etching composition of claim 1, wherein the composition comprises
(a) about 70 wt % to about 80 wt % water;
(b) about 0.6 wt % of neat HNO₃;
(c) a base comprising about 1.45 wt % of neat NH₄OH; and
(d) a halogen ion source comprising
(i) about 21 wt % neat HC; and
(ii) about 0.12 wt % of neat NH₄F.

31. The etching composition of claim 1, wherein the composition comprises
(a) about 10 wt % to about 15 wt % water;
(b) about 4.8 wt % of neat HNO₃;
(c) a base comprising about 7 wt % of amino(ethoxy) ethanol;
(d) a halogen ion source comprising about 0.05 wt % of neat HF; and
(e) about 75 wt % of neat acetic acid.

32. The etching composition of claim 1, wherein the composition comprises
(a) about 10 wt % to about 15 wt % water;
(b) about 4.8 wt % of neat HNO₃;
(c) a base comprising about 6 wt % of amino(ethoxy) ethanol;
(d) a halogen ion source comprising about 0.05 wt % of neat HF; and
(e) about 76 wt % of neat acetic acid.

33. The etching composition of claim 1, wherein the composition comprises
(a) about 10 wt % to about 15 wt % water;
(b) about 4.8 wt % of neat HNO₃;
(c) a base comprising about 6 wt % of amino(ethoxy) ethanol;
(d) a halogen ion source comprising about 0.04 wt % of neat HF; and
(e) about 78 wt % of neat acetic acid.

34. The etching composition of claim 1, wherein the composition comprises
(a) about 10 wt % to about 15 wt % water;
(b) about 9 wt % of neat HNO₃;
(c) a base comprising about 2.03 wt % of neat NH₄OH;
(d) a halogen ion source comprising about 0.05 wt % of neat HF; and
(e) about 77 wt % of sulfolane.

35-51. (canceled)

52. A method of selectively enhancing the etch rate of titanium nitride and molybdenum on a composite semiconductor device comprising titanium nitride and molybdenum, the method comprising the step of:
(i) contacting the composite semiconductor device comprising titanium nitride and molybdenum with a composition of claim 1,
wherein the titanium nitride is selectively etched over the molybdenum metal at a ratio of from about 1:3 to about 15.1:1.
